(19) United States
(12) Patent Application Publication
(10) Pub. No.: US 2005/0056858 A1
(43) Pub. Date: Mar. 17, 2005

(54) Light emitting device

(75) Inventors: Shinichi Kakiuchi, Saitama (JP); Shuzo Seo, Saitama (JP)

Correspondence Address: GREENBLUM & BERNSTEIN, P.L.C., 1950 ROLAND CLARKE PLACE, RESTON, VA, 20191, US

(73) Assignee: PENTAX Corporation, Tokyo (JP)

(21) Appl. No.: 10/938,506

(22) Filed: Sep. 13, 2004

(30) Foreign Application Priority Data
Sep. 17, 2003 (JP) P2003 - 324226

(51) Int. Cl. H01L 33/00

(52) U.S. Cl. 257/100

(57) ABSTRACT

Inner walls of a reflecting cup of a light emitting device include a base plane, a first pair of parallel planes, and a second pair of planes. The first pair of parallel planes are perpendicular to the base plane. The second pair of parallel planes are perpendicular to the base plane, and cross the first pair of parallel planes at right angles. An LED chip which emits a blue light is provided on the base plane. The LED chip is sealed in the cup by a fluorescent member including a fluorescent material, for example YAG. A ratio of a length of the first pair of parallel planes along a plane perpendicular to the optical axis of the light emitted from the LED chip and a length of the second pair of parallel planes along the perpendicular plane equals the aspect ratio of a photographing area of a camera which is used with the light emitting device.

### BACKGROUND OF THE INVENTION

1. Field of the Invention

The present invention relates to a light emitting device which is used for a lighting device of a camera.

2. Description of the Related Art

In recent years, high brightness LEDs and white LEDs have been developed, and the usage of these LEDs has diversified. For example, in place of a xenon lamp, a lighting device which includes a plurality of LEDs is used for a flash of a camera. A capacitor has to be mounted to use the xenon lamp. Accordingly, an inner space of camera is reduced. Further, the mounting of the capacitor is dangerous because of its high voltage. These problems can be solved by using LEDs.

However, leads and wires are provided around a chip of an LED. Namely, in the LED, light emitting members (chips) and non-emitting members (leads and wires) are arranged together. Accordingly, if light which is emitted from an LED is directly led to an object, the images of the chip and the other members which are close to the chip are projected on the object, and the luminance brightness becomes uneven.

Further, the light emitted from the LED may be projected on the object, spreading over an area broader than a photographing area of the camera. Namely, the light of the LED is illuminated outside of the photographing area of the camera. In such a case, there is the problem that it is difficult to secure enough light as illumination light.

### SUMMARY OF THE INVENTION

Therefore, an object of the present invention is to provide an illumination light without unevenness of luminance brightness, using a light emitting device which is provided with an LED chip.

In accordance with an aspect of the present invention, there is provided a light emitting device comprising: an LED chip, a case which includes an opening portion, and the inner walls of which have reflecting surfaces which reflect an incident light. The LED chip is positioned on a base plane facing the opening portion. A sectional form of the case which is cut along a plane perpendicular to the optical axis of the emitting light has a figure similar to a photographing area of a camera.

A sealing structure is placed in an optical path of the light emitted from the LED chip so that the LED chip is sealed in the case. The sealing structure diffuses and emits the emitting light from the opening portion.

Optionally, the inner walls include: a first pair of parallel planes, which are perpendicular to the base plane and a second pair of parallel planes which are perpendicular to the base plane, and which cross the first pair of parallel planes at right angles. A ratio of a length of the first pair of parallel planes along the plane perpendicular to the optical axis and a length of the second pair of parallel planes along the plane perpendicular to the optical axis equals an aspect ratio of the photographing area of the camera.

Optionally, the inner walls include: a first pair of inclined planes which are positioned symmetrically with the optical axis of the emitting light; and a second pair of inclined planes which are positioned symmetrically with the optical axis, crossing the first pair of inclined planes. A ratio of a length of the first inclined planes along the perpendicular plane and a length of the second inclined planes along the perpendicular plane equals an aspect ratio of the photographing area of the camera.

Preferably, the first pair of inclined planes and the second pair of inclined planes are inclined to the optical axis at the same angle.

For example, the LED chip emits a blue light, and the sealing structure includes a fluorescent material which emits a diffused white light when the blue light is incident on the sealing structure.

According to the present invention, the case, in which the LED chip is provided, is structured such that its sectional form which is cut along a plane perpendicular to the optical axis of the emitting light, has a figure similar to the photographing area of the camera. Further, the LED chip is sealed in the case by the sealing structure which diffuses the emitted light. Accordingly, when the light emitted from the opening portion of the case is led to the object through the leading optical system, unevenness of the luminance brightness on the object can be prevented, and the illuminating light can be efficiently supplied to the object.

### BRIEF DESCRIPTION OF THE DRAWINGS

The objects of the present invention will be better understood from the following description, with reference to the accompanying drawings, in which:

FIG. 1 is a view which conceptionally shows a positional relationship between members of a lighting unit to which a first embodiment according to the present invention is applied;

FIG. 2 is a plan view of a reflecting cup of the first embodiment;

FIG. 3 is a sectional view of the reflecting cup of the first embodiment;

FIG. 4 is a view which coneptionally shows the lighting unit, a camera, and an object;

FIG. 5 is a plane view of a reflecting cup of a second embodiment of the present invention; and

FIG. 6 is a sectional view of the reflecting cup of the second embodiment.

### DESCRIPTION OF THE PREFERRED EMBODIMENTS

The present invention will now be described with reference to an embodiment shown in the drawings.

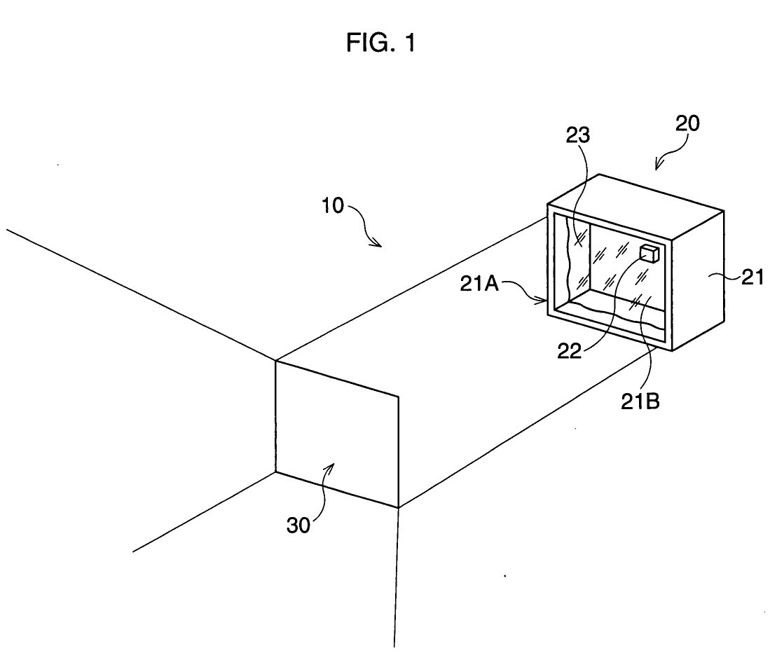

FIG. 1 is a view which conceptionally shows a lighting unit to which a first embodiment according to the present invention is applied.

A lighting unit 10 includes a light emitting device 20 and a leading optical system 30. A reflecting cup 21 of the device 20 is an approximately rectangular parallelpiped, and hollow. An opening portion 21A is formed in the reflecting cup 21. An inner surface of the reflecting cup 21 is made of a member which reflects incident light. In the reflecting cup 21, an LED chip 22 including a p-n junction is provided on a base plane 21B, which is opposite to the opening portion 21A. The LED chip 22 is a blue light emitting diode. The LED chip 22 is sealed by a fluorescent member 23 including a fluorescent material, for example, YAG (Yttrium Aluminum Garnet).

Light emitted from the LED chip 22 is converted to a white light and diffused by the fluorescent material included in the fluorescent member 23. The white light is emitted from the opening portion 21A. After being emitted from the opening portion 21A, the white light is led to the object through the leading optical system 30. Note that, in FIG. 1, the leading optical system 30 is conceptionally depicted to clarify the positional relationship between the device 20 and the optical system 30.

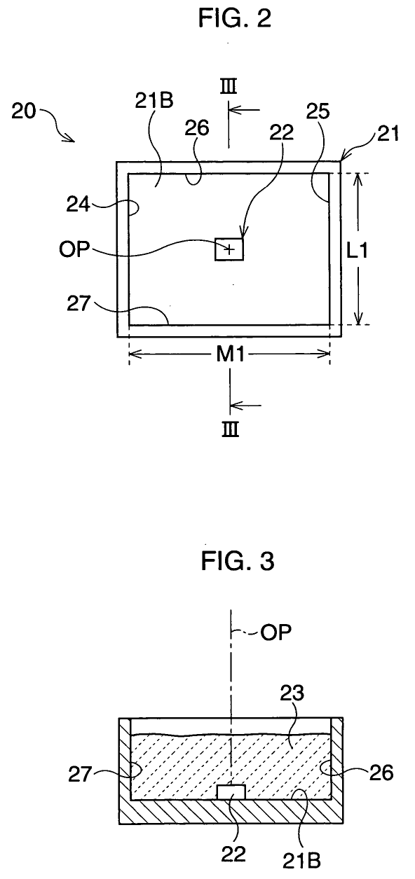

FIG. 2 is a plane view of the light emitting device 20, and FIG. 3 is a sectional view taken in the direction of the arrows substantially along the line III-III of FIG. 2. The inner walls of the cup 21 include the base plane 21B, a pair of parallel planes 24, 25, and a pair of parallel planes 26, 27. The pair of parallel planes 24, 25 are perpendicular to the base plane 21B. The pair of parallel planes 26, 27 are perpendicular to the base plane 21B, and cross the pair of parallel planes 24, 25 at right angles.

A length L1 is a length of the pair of parallel planes 24, 25 along a plane perpendicular to the optical axis OP of the emitting light of the LED chip 22. Namely, in the first embodiment, the length L1 corresponds to the lateral length of the base plane 21B. A length M1 is a length of the parallel planes 26, 27 along the perpendicular plane. The inner walls of the cup 21 are structured such that the ratio of the lengths L1 and M1 equals an aspect ratio of a photographing area of one frame of a camera which is used with the light emitting device 10. Note that the aspect ratio means a ratio between a longitudinal side and a lateral side of the photographing area.

In other words, the cup 21 is structured such that the sectional form of the cup 21, which is cut along the plane perpendicular to the optical axis OP, has a figure similar to the photographing area. Note that the LED chip 22 is connected to leads through wires, however the leads and the wires are omitted in FIG. 3 to clarify the drawing.

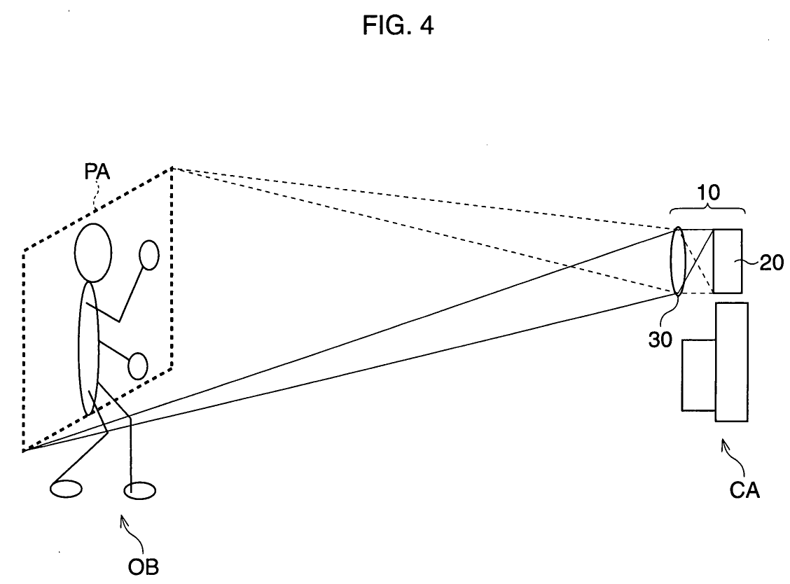

The fluorescent member 23 is applied on the inner walls of the cup 21, and the inner walls of the cup 21 are structured as described above. Accordingly, an area PA of the light, which is emitted from the light emitting device 20 and led to the object OB through the leading optical system 30, is rectangular, as shown in FIG. 4. Further, the aspect ratio of the area PA equals the aspect ratio of the photographing area of a camera CA which is used with the device 20. Namely, the area which is illuminated by the illumination light has a figure similar to the photographing area of the camera CA. Accordingly, since the illumination light is not illuminated out of the photographing area of the camera CA, the emitting light of the device 20 can be efficiently used. Further, since the inner walls of the cup 21 include two pairs of parallel planes, it is easy to make the cup 21.

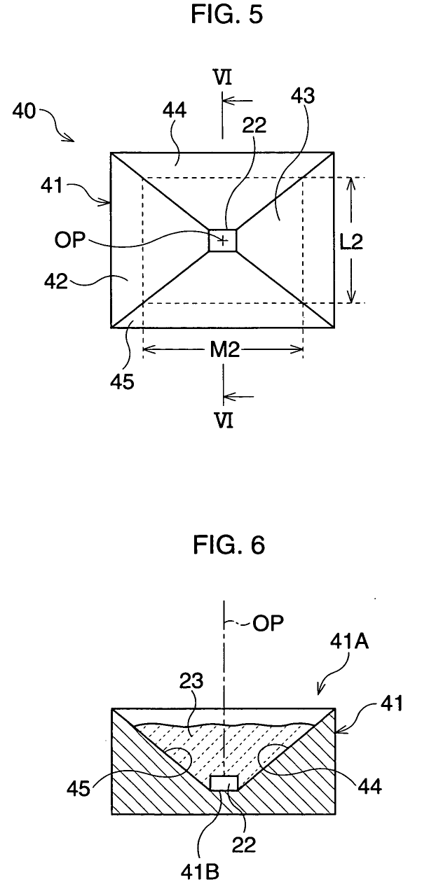

FIG. 5 is a plane view of a light emitting device 40 to which a second embodiment according to the present invention is applied. FIG. 6 is a sectional view taken in the direction of the arrows substantially along the line VI-VI of FIG. 4. Similarly to the first embodiment, a cup 41 of the device 40 is an approximately rectangular parallelpiped, and hollow. The LED chip 22 which emits a blue light is provided on a base plane 41B which faces an opening portion 41A. An inner surface of the reflecting cup 41 is made of a member which reflects incident light. The LED chip 22 is sealed by the fluorescent member 23 similarly to the first embodiment. Further, similarly to the first embodiment, the device 40 constitutes a light emitting device with the leading optical system 30.

The inner walls of the reflecting cup 41 include a pair of inclined planes 42, 43 and a pair of inclined planes 44, 45. The pair of inclined planes 42, 43 are positioned symmetrically with the optical axis OP of the emitting light of the LED chip 22. The pair of inclined planes 44, 45 are positioned symmetrically with the optical axis OP, crossing the pair of inclined planes 42, 43.

A length L2 is a length of the planes 42, 43, which is along a plane perpendicular to the optical axis OP. A length M2 is a length of the planes 44, 45, which is along the perpendicular plane. The inner walls of the cup 41 are structured such that the ratio of the lengths L2 and M2 at all times equals an aspect ratio of a photographing area of one frame of a camera, for example the above-mentioned camera CA, which is used with the light emitting unit including the light emitting device 40.

The pair of inclined planes 42, 43 incline to the optical axis OP at the same angle, from the base plane 41B to the opening portion 41A. Further, the pair of inclined planes 44, 45 incline to the optical axis OP at the same angle, from the base plane 41B to the opening portion 41A.

An area of the illumination light which is emitted from the light emitting device 40 and is led to the object through the leading optical system 30 is a rectangular. Further, the aspect ratio of the area equals the aspect ratio of the photographing area of the camera CA. Namely, the area illuminated by the illumination light has a figure similar to the photographing area of the camera CA. Accordingly, the same effect as the first embodiment can be obtained by the second embodiment. Further, since the base plane 41B and two pairs of inclined planes constitute the inner walls in the second embodiment, the amount of the fluorescent member 23 which is applied on the inner walls of the cup 41 can be reduced.

The present disclosure relates to subject matter contained in Japanese Patent Application No. 2003-324226 (filed on Sep. 17, 2003) which is expressly incorporated herein, by reference, in its entirety.

1. A light emitting device comprising:
an LED chip;
a case which includes an opening portion, and the inner walls of which have reflecting surfaces which reflect an incident light, said LED chip being positioned on a base plane facing said opening portion, a sectional form of said case which is cut along a plane perpendicular to the optical axis of said emitting light having a figure similar to a photographing area of a camera;
a sealing structure which is placed in an optical path of the light emitted from said LED chip such that said LED chip is sealed in said case, said sealing structure diffusing and emitting said emitting light from said opening portion.

2. A light emitting device according to claim 1, wherein said inner walls include: a first pair of parallel planes, which are perpendicular to said base plane; and a second pair of parallel planes which are perpendicular to said base plane, and which cross said first pair of parallel planes at right angles, and
a ratio of a length of said first pair of parallel planes along said plane perpendicular to the optical axis and a length of said second pair of parallel planes along said plane perpendicular to the optical axis equals an aspect ratio of said photographing area of said camera.

3. A light emitting device according to claim 1, wherein said inner walls include: a first pair of inclined planes which are positioned symmetrically with said optical axis of said emitting light; and a second pair of inclined planes which are positioned symmetrically with said optical axis, crossing said first pair of inclined planes, and
a ratio of a length of said first inclined planes along said perpendicular plane and a length of said second inclined planes along said perpendicular plane equals an aspect ratio of said photographing area of said camera.

4. A light emitting device according to claim 3, wherein said first pair of inclined planes and said second pair of inclined planes are inclined to said optical axis at the same angle.

5. A light emitting device according to claim 1, wherein said LED chip emits a blue light, and said sealing structure includes a fluorescent material which emits a diffused white light when said blue light is incident on said sealing structure.
